(19) United States
(12) Patent Application Publication
(10) Pub. No.: US 2026/0261095 A1
(43) Pub. Date: Sep. 3, 2026

(54) MULTI-WAVELENGTH EMITTER

(71) Applicant: Lumentum Operations LLC., San Jose, CA (US)

(72) Inventors: Yeyu ZHU, San Jose, CA (US); Jun YANG, Cupertino, CA (US)

(21) Appl. No.: 19/236,495

(22) Filed: Jun. 12, 2025

Related U.S. Application Data
(60) Provisional application No. 63/764,704, filed on Feb. 28, 2025.

(51) Int. Cl. H01S 5/183

(52) U.S. Cl. CPC H01S 5/18369; H01S 5/18311; H01S 2301/163; H01S 2301/166

(57) ABSTRACT

In some implementations, an emitter device (such as a vertical cavity surface emitting laser (VCSEL) device) may include a substrate layer, a set of epitaxial layers deposited on the substrate layer, at least one active region formed in the set of epitaxial layers, and multiple sidewall reflectors. The emitter device may be configured such that electrical pumping provides an optical gain within the at least one active region for lasing at a first wavelength based on the set of epitaxial layers and lasing at a second wavelength based on the multiple sidewall reflectors.

### CROSS-REFERENCE TO RELATED APPLICATION

This patent application claims priority to U.S. Patent Application No. 63/764,704, filed on Feb. 28, 2025, and entitled “MULTI-WAVELENGTH EMITTER.” The disclosure of the prior application is considered part of and is incorporated by reference into this patent application.

### TECHNICAL FIELD

The present disclosure relates generally to emitters and to multi-wavelength emitters.

### BACKGROUND

A vertical-emitting laser device, such as a vertical cavity surface emitting laser (VCSEL), is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

In some implementations, a vertical cavity surface emitting laser (VCSEL) device may include a substrate layer, a set of epitaxial layers deposited on the substrate layer, at least one active region formed in the set of epitaxial layers, and multiple sidewall reflectors, wherein the VCSEL device is configured such that electrical pumping provides an optical gain within the at least one active region for lasing at a first wavelength based at least in part on the set of epitaxial layers and lasing at a second wavelength based at least in part on the multiple sidewall reflectors.

In some implementations, an emitter device may include a substrate layer, a set of epitaxial layers deposited on the substrate layer, at least one active region formed in the set of epitaxial layers, and multiple sidewall reflectors, wherein the VCSEL device is configured such that electrical pumping provides an optical gain within the at least one active region for lasing at a first wavelength based at least in part on the set of epitaxial layers and lasing at a second wavelength based at least in part on the multiple sidewall reflectors.

In some implementations, a VCSEL device may include a substrate layer, a set of epitaxial layers disposed on the substrate layer, a plurality of active regions formed in the set of epitaxial layers, and multiple sidewall reflectors, wherein the VCSEL device is configured such that electrical pumping provides an optical gain within the plurality of active regions for lasing at a first wavelength based at least in part on the set of epitaxial layers and lasing at a plurality of second wavelengths are based at least in part on the multiple sidewall reflectors, and the plurality of second wavelengths are respectively associated with the plurality of active regions.

### BRIEF DESCRIPTION OF THE DRAWINGS

FIGS. 1A and 1B are diagrams respectively depicting a top view and a cross-sectional view of an example emitter.

FIG. 1C is a diagram depicting a gain curve corresponding to the emitter of FIGS. 1A and 1B.

FIG. 2A shows a cross-sectional view of an example emitter that enables a multi-wavelength output according to one or more implementations.

FIG. 2B shows an example wavelength coupling diagram of the multi-wavelength output corresponding the emitter of FIG. 2A according to one or more implementations.

FIG. 2C shows a wavelength-intensity graph corresponding to the emitter of FIG. 2A according to one or more implementations

FIG. 3A shows a cross-sectional view of an example multi-junction emitter that enables a multi-wavelength output according to one or more implementations.

FIG. 3B shows an example gain curve of the multi-wavelength output corresponding the multi-junction emitter of FIG. 3A according to one or more implementations.

FIG. 3C shows a wavelength-intensity graph corresponding to the multi-junction emitter of FIG. 3A according to one or more implementations.

FIG. 4 shows an example fabrication process for creation of multiple sidewall reflectors included in an emitter according to one or more implementations.

### DETAILED DESCRIPTION

The following detailed description of example implementations refers to the accompanying drawings. The same reference numbers in different drawings may identify the same or similar elements.

Lasers (e.g., including vertical-cavity surface-emitting lasers (VCSELs)) may have an optical-amplifying mechanism within an optical resonator of the laser (e.g., a cavity). In some examples, optical amplification may result in a laser that lases in accordance with “optical modes” (e.g., wavelengths and orientations that resonate in a resonator of a laser and are amplified by an amplifier of the laser). In accordance with the selective nature of resonance in lasers, optical modes may occur only at a few specific combinations of wavelength and orientation. Practical lasers typically have structures and features to limit which optical modes are enabled for operation. For instance, a laser may be configured to allow operation at a single axial orientation and a single wavelength (e.g., a “single-mode” laser).

Laser optical modes include longitudinal modes and transverse modes. Longitudinal modes have an axial orientation and may be associated with wavelengths that resonate in the length of the resonator of the laser. Transverse modes have propagation components askew to the axis (e.g., reflecting side-to-side as well as end-to-end within the cavity of the laser). In some examples, there may be a discrete number of possible transverse modes for a laser based on resonance capabilities of the laser. In some examples, a laser may have a “fundamental” (“zero-order”) transverse mode, which may be a longitudinal mode that has propagation components near the cavity axis (e.g., no side-to-side resonance). The fundamental transverse mode may have a single, centralized, intensity lobe at the laser output, where the laser output carries on the predominantly-axial propagation characteristics. Additionally, “higher-order” transverse modes may have off-axis propagation components (e.g., enabling side-to-side resonance). Typically, the higher-order transverse modes may be askew to the cavity axis (e.g., neither parallel nor perpendicular to the cavity axis). In some examples, one or more higher-order transverse modes may have multiple intensity lobes at the laser output, where propagation of the laser output carries one or more off-axis components. Based on higher-order transverse modes resulting in off-axis components, control of external propagation from the laser may be more challenging. Accordingly, a laser may be configured to limit one or more higher-order transverse modes in order to increase control of the external propagation. In some examples described herein, the term “single-mode laser” may apply to a laser supporting multiple longitudinal modes, and only a fundamental (zero-order) transverse mode.

One or more types of lasers may include respective resonator cavities that are long and thin relative to the optical wavelength (e.g., have a high aspect ratio), which may make non-zero-order transverse modes lossy and hence quenched. Conversely, a VCSEL may include a resonator cavity that is short and wide relative to the optical wavelength (e.g., a low aspect ratio). Accordingly, a VCSEL may support a greater number of transverse modes compared to other types of lasers. Additionally, based on the low aspect ratios of VCSELs, a lowest-order non-fundamental transverse mode can have a significantly different wavelength compared to the base fundamental transverse mode of a same longitudinal resonance order. In some VCSEL designs, one or more implantation features (e.g., chemical implantations) may be applied to the laser-device to confine the gain current and absorb scattered and laterally-propagating light, which suppresses higher-order transverse modes from reaching a lasing threshold. Accordingly, a photonic structure that is capable of outputting in multiple wavelength bands may include multiple emitters (e.g., multiple laser chips, such as multiple VCSEL chips) that respectively output multiple wavelength bands. However, including multiple emitters in a photonic structure may increase the size and/or the cost of the photonic structure.

According to some implementations described herein, a photonic structure may include at least one emitter (e.g., a VCSEL chip) that can perform lasing at multiple wavelength spectral lines. For example, an emitter may not include the one or more implantation features (that suppress the generation of non-fundamental transverse modes), and instead may include multiple sidewall reflectors that enable the VCSEL to output one or more transverse modes. For example, the multiple sidewall reflectors may be comprised of metal and/or layered dielectric strata that reflect off-axis optical propagation sufficient to allow one or more non-fundamental transverse modes to become established. Such establishment of one or more non-fundamental transverse modes can enable the emitter to output different wavelengths of light for a same longitudinal resonance order. Accordingly, the emitter can lase at different wavelengths within a gain curve defined by a fixed set of configurations (e.g., the set of configurations including a set of epitaxial layer grown on a substrate layer, a distributed Bragg reflector (DBR), and/or physical structure of the emitter). By including one or more emitters capable of multiple wavelength outputs, a photonic structure may achieve a multi-wavelength output while including fewer emitters, reducing the cost, size, and complexity of the photonic structure.

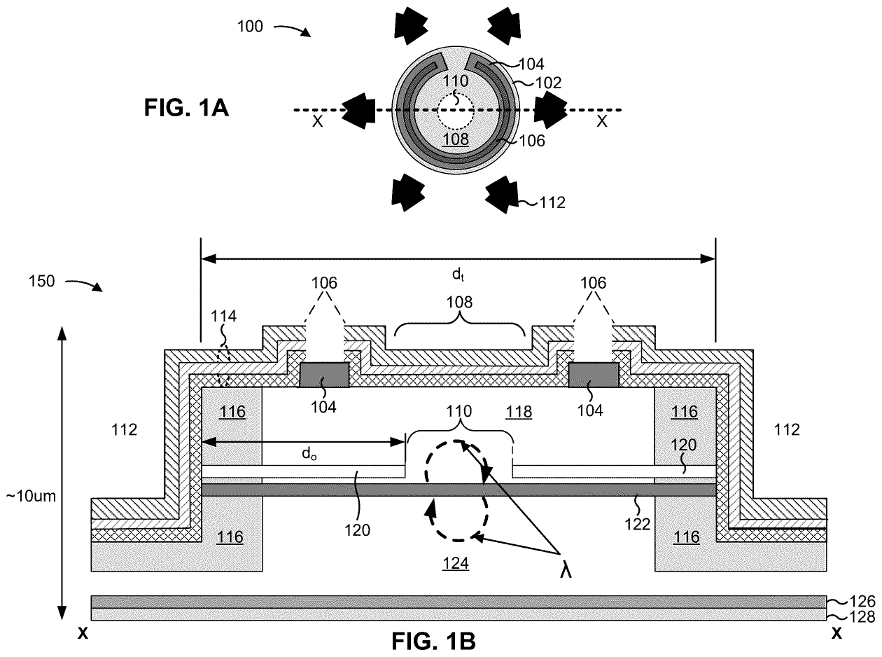

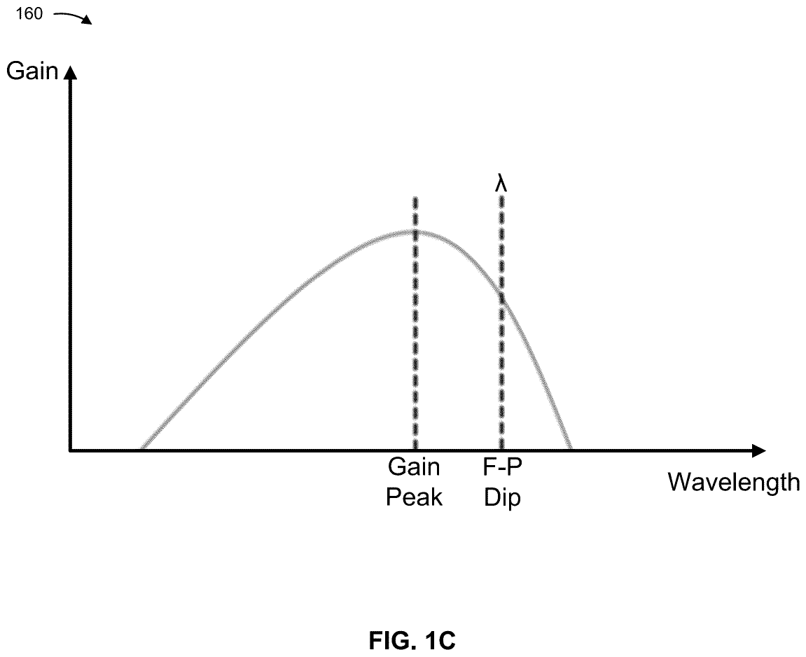

FIGS. 1A and 1B are diagrams depicting a top view of an example emitter 100 and a cross-sectional view 150 of example emitter 100 along the line X-X, respectively. FIG. 1C shows a gain curve 160 for a wavelength output for the emitter 100 of FIGS. 1A and 1B. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g. a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dt. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a photonic crystal surface emitting laser (PCSEL), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g. a dielectric passivation/mirror layer), and an ohmic metal layer 104. As shown, emitter 100 may have, for example, a total height that is approximately 10 micrometers (μm).

Backside cathode layer 128 may include a layer that makes electrical contact with substrate layer 126. For example, backside cathode layer 128 may include an annealed metallization layer, such as a gold-germanium-nickel (AuGeNi) layer, a palladium-germanium-gold (PdGeAu) layer, or the like.

Substrate layer 126 may include a base substrate layer upon which epitaxial layers are grown. For example, substrate layer 126 may include a semiconductor layer, such as a gallium arsenide (GaAs) layer, an indium phosphide (InP) layer, and/or another type of semiconductor layer.

Bottom mirror 124 may include a bottom reflector layer of emitter 100. For example, bottom mirror 124 may include a DBR.

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an aluminum oxide (Al₂O₃) layer formed as a result of oxidation of an aluminum arsenide (AlAs) or aluminum gallium arsenide (AlGaAs) layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 micrometers (μm) to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In other words, the implant isolation material 116 may create regions of higher refractive index contrast within the cavity of the emitter 100. This refractive index variation confines the optical field and suppresses higher-order transverse modes by increasing attenuation or absorption as the higher-order transverse modes propagate within the emitter 100, ensuring that only the fundamental transverse mode (which experiences the least loss and has the highest gain) is able to form and propagate effectively. This selective confinement helps maintain single-mode operation of the emitter 100. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a silicon dioxide (SiO₂) layer, a silicon nitride (Si₃N₄) layer, an Al₂O₃ layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

The emitter 100 may include a DBR mirror pair, such as the top mirror 118 and the bottom mirror 124. In some examples, a DBR from the DBR mirror pair may be made of multiple alternatively stacked high-index and low-index layers. Additionally, the high-index and low-index layers may have respective optical equivalent thicknesses as defined with reference to Equation 1:

$${d}_{optical} = \frac{( 2 m + 1 ) λ}{4} \qquad ( 1 )$$

where d_{optical} is the actual layer thickness divided by the layer refractive index, m is an integer (e.g., 0, 1, 2, or the like) and λ is the nominal free-space wavelength of the DBR reflection band. In some examples, the DBR mirror pair may form a DBR cavity of the emitter 100 that supports longitudinal modes for optical output.

As shown FIG. 1B, the emitter 100 may have an output wavelength of λ. In some examples, the output wavelength (λ) of the emitter 100 may be based on a longitudinal mode defined by the DBR cavity.

The emitter 100 outputs light at the output wavelength (λ) determined by the interplay between the DBR mirror pair (e.g., the top mirror 118 and the bottom mirror 124) and the active region 122. For instance, a separation between these mirrors defines the longitudinal modes of the emitter 100, with the cavity length determining the specific wavelengths that can resonate. The active region 122, typically composed of quantum wells, provides the gain medium where electron-hole recombination occurs, emitting photons. The gain curve 160 of the emitter 100 (e.g., the gain curve 160, as shown in FIG. 1C and described in more detail below) is defined by the material properties of the active region 122 and the quantum well design, which determine the range of wavelengths over which the medium can amplify light. The wavelength of the emitted light is defined by the overlap between the gain spectrum of the active region and the resonant modes of the optical cavity, ensuring that only specific wavelengths with sufficient gain are amplified and emitted, i.e., exceed lasing threshold.

FIG. 1C illustrates the gain curve 160 corresponding to the emitter 100. For example, the gain curve 160 represents the variation of optical gain provided by the active medium of the emitter 100 as a function of wavelength. The gain curve 160 shows the range of wavelengths over which the medium can amplify light, with the peak of the curve indicating the wavelength at which the gain is highest. As shown in FIG. 1C, the output wavelength (λ) of the emitter 100 may correspond to a Fabry-Pérot (F-P) dip associated with the DBR mirror pair. For example, the F-P dip may be a dip, relative to a gain peak, in the optical power spectrum of an output of the emitter 100 caused by interference in the DBR cavity. The F-P dip may be based on destructive interference that results from longitudinal mode competition and incomplete coherence between adjacent longitudinal modes. In some examples, a length of the output wavelength of the emitter 100 may change as a function of temperature and a location of the output wavelength on the gain curve 160. For example, an output wavelength at the F-P dip may shift approximately 0.07 nanometers (nm) per degree Celsius (nm/° C.) and an output wavelength at the gain peak may shift approximately 0.30 nm/° C. As the temperature changes, the F-P dip may not be aligned with the peak gain wavelength.

As indicated above, FIGS. 1A, 1B, and 1C are provided as examples. Other examples may differ from what is shown in and described with regard to FIGS. 1A, 1B, and 1C.

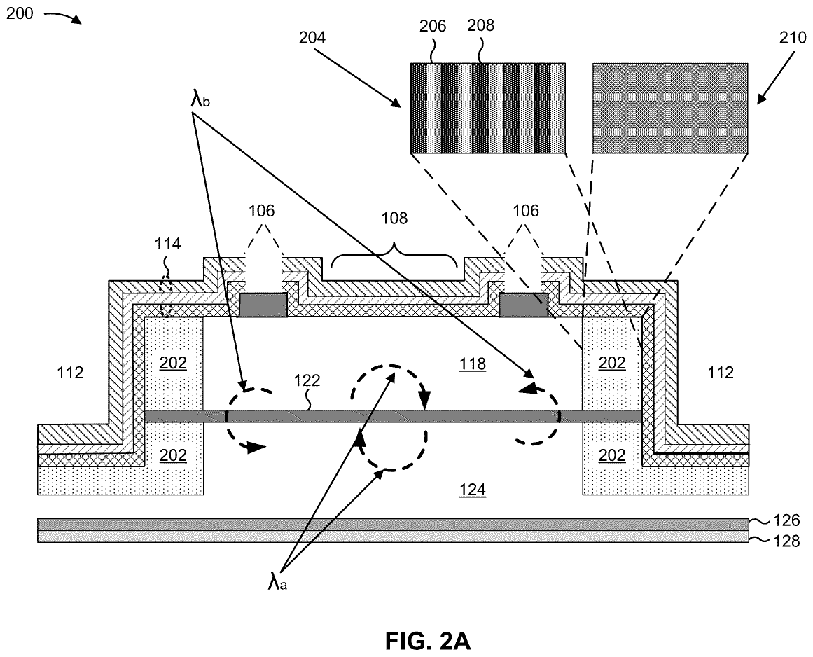

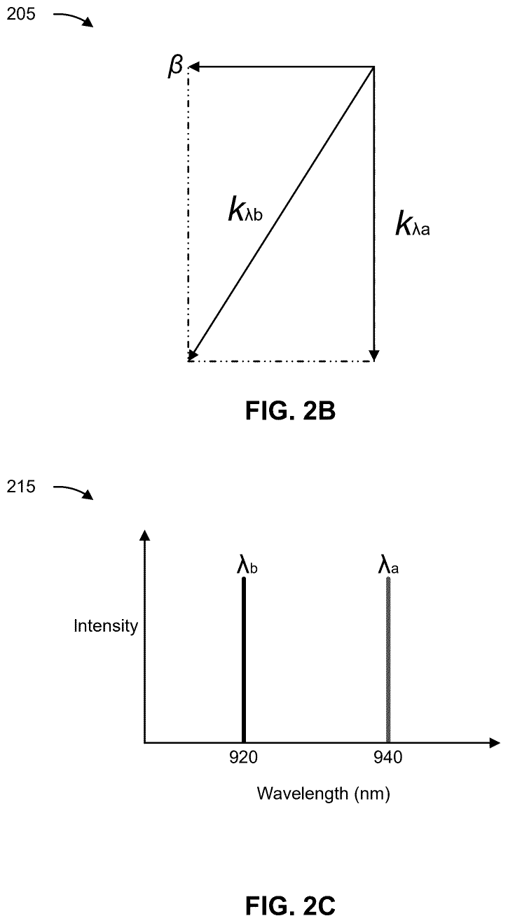

FIG. 2A shows a cross-sectional view of an example emitter 200 that enables a multi-wavelength output according to one or more implementations. FIG. 2B shows an example wavelength coupling diagram 205 of the multi-wavelength output corresponding the emitter 200 of FIG. 2A according to one or more implementations. FIG. 2C shows a wavelength-intensity graph 215 corresponding to the emitter 200 of FIG. 2A according to one or more implementations. In some implementations, the emitter 200 may be a VCSEL device. As shown in FIG. 2A, the emitter 200 may implement one or more components and/or aspects of the emitter 100. For example, as shown in FIG. 2A, the emitter 200 includes the via 106, the optical aperture 108, the trenches 112, the top mirror 118, the active region 122, the bottom mirror 124, the substrate layer 126, and the backside cathode layer 128. In some other implementations, the emitter 200 may include additional components and/or aspects of the emitter 100. Additionally, or alternatively, one or more components and/or aspects of the emitter 200 shown in FIG. 2A may not be included in other implementations.

As described elsewhere herein, the bottom mirror 124, active region 122, and/or top mirror 118 may be a set of epitaxial layers deposited on the substrate layer 126, where the active region 122 may be formed in the set of epitaxial layers. Additionally, the emitter 200 does not include the implant isolation material 116 of the emitter 100. Rather, the emitter 200 includes multiple sidewall reflectors 202 (e.g., in place of the implant isolation material 116). Accordingly, the emitter 200 may be configured such that electrical pumping provides an optical gain within the active region 122 for lasing at a first wavelength (e.g., λₐ) based on the set of epitaxial layers, and lasing at a second wavelength (e.g., λ_{b}) based on the multiple sidewall reflectors 202.

The first output wavelength (λₐ) may be defined by a fundamental longitudinal mode based on the DBR cavity of the emitter 200 (e.g., end-to-end resonance) and the second output wavelength (λ_{b}) may be defined by a non-fundamental transverse mode that spans across the multiple sidewall reflectors 202 (e.g., side-to-side resonance). To facilitate the light reflecting between the multiple sidewall reflectors 202 in the horizontal direction, the emitter 200 may omit an implant isolation material (e.g., implant isolation material 116) or other feature(s) that may otherwise confine current to the vertical direction. Accordingly, the current can spread to the horizontal direction of the DBR cavity of the emitter 200, enabling enough gain to produce the second output wavelength (λ_{b}).

In some implementations, the multiple sidewall reflectors 202 comprise a dielectric mirror pair 204 that includes one or more alternating layers of a first dielectric material 206 and a second dielectric material 208. For example, the dielectric mirror pair 204 may be an optical mirror composed of multiple thin layers of transparent dielectric materials. By alternating between materials of high and low refractive indexes, the dielectric mirror pair 204 may achieve a high reflectivity through constructive interference of reflected light. For instance, the first dielectric material 206 may have a first refractive index that is greater than or equal to a refractive index threshold (e.g., a high refractive index) and the second dielectric material 208 may have a refractive index that is less than the refractive index threshold (e.g., a low refractive index). In some implementations, the refractive index threshold may be 2.0, or some other value based on one or more design characteristics of the emitter 200. The second dielectric material 208 (e.g., low refractive index material) may include silicon dioxide (SiO₂), magnesium fluoride (MgF₂), aluminum fluoride (AlF₃), Al₂O₃, and/or any other material with a low refractive index (e.g., n<2.0). The first dielectric material 206 (e.g., high refractive index material) may include silicon nitride (Si₃N₄), titanium dioxide (TiO₂), tantalum pentoxide (Ta₂O₅), zirconium dioxide (ZrO₂), zinc sulfide (ZnS), and/or any other material with a high refractive index (e.g., n≥2.0). The dielectric mirror pair 204 may be designed with a number of alternating materials and a thickness to target a specific wavelength band, enabling fine tuning of the second output wavelength (λ_{b}). In other words, the value of the λ_{b} may be based on the number of layers of the first dielectric material 206, the number of layers of the second dielectric material 208, a thickness of each layer of the first dielectric material 206, a thickness of each layer of the second dielectric material 208, and/or a total thickness of the dielectric mirror pair 204.

In some implementations (e.g., alternative to the dielectric mirror pair 204), the multiple sidewall reflectors 202 comprise a metal layer 210. For instance, the metal layer 210 may include one or more layers of one or more plated metals. The term “plated metal” refers to an object that has been coated with a layer of a metal. Additionally, the metal layer 210 may be comprised of one or more metals with high-reflectivity such as silver, aluminum, and/or gold, among other high-reflectivity metals. For example, silver has the highest reflectivity of any elemental metal, reflecting up to 99% of visible light. Additionally, aluminum is highly reflective, particularly in the ultraviolet and visible spectrum, where reflectivity can reach up to 92% in the visible spectrum, and aluminum is also lightweight and corrosion-resistant. Additionally, gold is highly reflective in the infrared and visible spectrum, with a reflectivity of approximately 95% in the infrared spectrum. Accordingly, the one or more types of metals used in the metal layer 210 may be based on manufacturing costs of the emitter 200 and/or the desired range of wavelength light emission configured for the emitter 200.

FIG. 2B shows the wavelength coupling diagram 205. The wavelength coupling diagram 205 shows a first wave vector (k_{λa}) for propagation of light with the first wavelength output (λₐ) and a second wave vector (k_{λb}) for propagation of light with the second wavelength output (λ_{b}). The first wave vector (k_{λa}) propagates in the vertical direction and may be based on one or more characteristics of DBR cavity of the emitter 200 (e.g., defined by the set of epitaxial layers). The wavelength vector coupling theory for light output of λ_{b} from the emitter 200 describes how the wave vector k_{λb} propagates at an angle, rather than purely vertically or horizontally. While the wave vector k_{λa} for the emission wavelength λₐ is aligned vertically (e.g., indicating the propagation of light defined by the F-P resonance dip within the vertical cavity of the emitter 200), the propagation of light at λ_{b} is more complex. The wave vector k_{λb} for λ_{b} is angled, reflecting the influence of both the vertical cavity (characterized by the F-P dip and k_{λa}) and the horizontal cavity, which is influenced by the multiple sidewall reflectors 202. Accordingly, this angled propagation causes the light at λ_{b} to be subject to interactions within the vertical cavity, defined by the top mirror 118 and the bottom mirror 124, as well as within the horizontal cavity, where sidewall reflectors 202 enable lasing at a non-fundamental transverse mode. The combined effect of these cavities determines the overall propagation characteristics of λ_{b}, leading to a more intricate coupling of wave vectors. This dual-cavity influence can affect the mode structure, stability, and efficiency of the emitter 200. Therefore, as shown by the wavelength coupling diagram 205, the emitter is configured to output the first wavelength (λₐ) according to a first wave vector (k_{λa}) that propagates in a vertical direction that is perpendicular to the set of epitaxial layers (e.g., up and down the vertical cavity), and output the second wavelength (λ_{b}) according to a second wave vector (k_{λb}) that propagates in a direction at a non-zero angle (e.g., both a horizontal component and vertical component) relative to the vertical direction based on the multiple sidewall reflectors 202.

FIG. 2C shows an example wavelength-intensity graph 215 corresponding to the emitter 200. According to some examples, the wavelength-intensity graph 215 shows intensities of multiple wavelength outputs for the emitter 200. For example, the wavelength-intensity graph 215 shows a first intensity of the first wavelength output (λₐ) and a second intensity of the second wavelength output (λ_{b}). As described elsewhere herein, the first wavelength output (λₐ) may be defined by the F-P dip on a gain spectrum (e.g., 940 nm). As described herein, because of the low aspect ratio of the VCSEL cavity, there may be several transverse resonance modes available within the spectral range of the gain curve. To restrict/reduce the number of lasing wavelengths for one or more embodiments, the implantation material, sidewall reflectivity, and/or gain current profile may be configured according to well-known relationships such that the transverse modes require higher amount of gain than the fundamental axial mode (λₐ) to exceed lasing threshold. This serves to restrict emission at λ_{b} to the transverse-resonance mode that is most proximal to the peak gain wavelength in the gain spectrum (e.g., 920 nm). This alignment enhances the overall performance and efficiency of the emitter 200 by leveraging the inherent amplification properties of the gain medium. Therefore, the first wavelength output (λₐ) may be different from the second wavelength output (λ_{b}). In other words, the optical gain is defined by an optical gain curve such that the first wavelength (λₐ) is located at an F-P dip of the optical cavity, and the second wavelength (λ_{b}) is located at a gain peak of the optical gain curve. Additionally, the intensity of the first wavelength output (λₐ) and the intensity of the second wavelength output (λ_{b}) may be the same intensity or different intensities.

In some implementations, as a temperature of the emitter 200 changes, the mode resonance wavelengths change at a first rate of change and the peak of the gain curve changes at a second rate of change. For instance, the first rate of change for the resonance wavelengths may be proportional to the product of refractive index rate of change and the thermal expansion coefficient. In the example of emitter 200, the net first rate of change may be 0.07 nm/° C. (e.g., similar to the output wavelength of the lone axial mode resonance λₐ). However, as the gain peak shifts at a different rate than the mode-resonance wavelengths, the transverse-mode output wavelength shifts among the available transverse-mode resonances to remain proximal to the gain peak. Thereby, the second rate of change for the second wavelength (λ_{b}) may be different than the rate of change for the first wavelength (λₐ). In the example of emitter 200, the second rate of change may be effectively 0.30 nm/° C. Accordingly, as a temperature of the emitter 200 changes, the first wavelength (λₐ) located at the F-D dip of the gain curve may change at a first wavelength rate while the second wavelength (λ_{b}) located at the gain peak of the gain curve may change at a second wavelength rate that is greater than the first wavelength rate.

In some implementations, the emitter 200 can be used as a radio frequency (RF) generator, where the RF may be equal to Δλ=|λₐ−λ_{b}|. In some examples, a frequency of the RF generator may be tunable as the temperature changes. Additionally, the techniques described herein may be applicable to various VCSEL architectures (such as oxide-confined VCSEL, implant-only VCSEL, mesa type devices, or the like). Additionally, the techniques described herein may be applicable across a range of wavelengths (e.g., 800 nm to 2000 nm) and across different material systems (e.g., GaAs substrates, InP substrates, or the like). Additionally, or alternatively, the emitter 200 is an example of a top-emitting VCSEL, but the techniques described herein can also be applicable to bottom-emitting VCSELs. Additionally, or alternatively, a number of emitters 200 included in a photonic structure, sizes of the emitters, and/or array shapes described herein are examples that can be varied depending on the application. Additionally, or alternatively, emitters with a VCSEL structure disclosed herein can have varied aperture shapes.

As indicated above, FIGS. 2A, 2B, and 2C are provided as examples. Other examples may differ from what is shown in and described with regard to FIGS. 2A, 2B, and 2C.

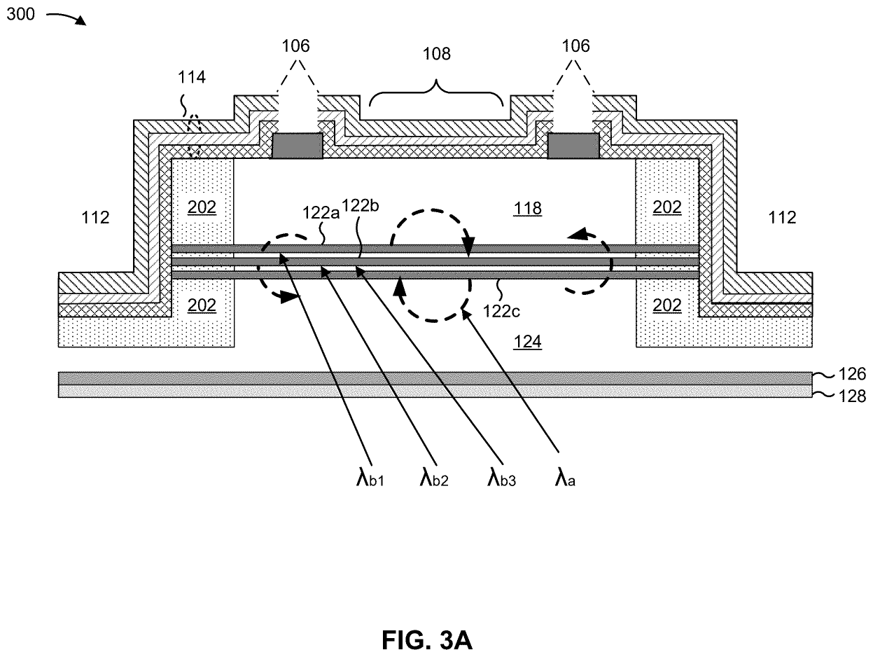

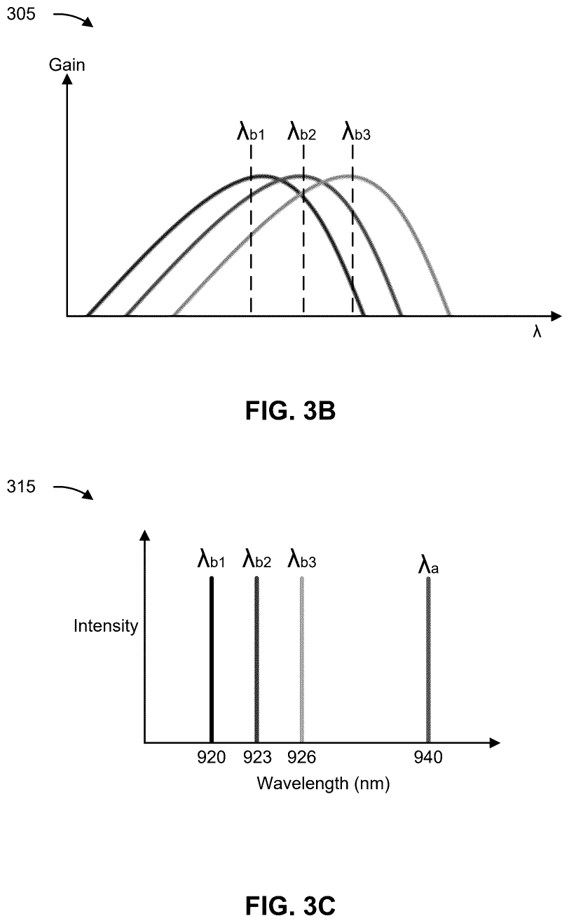

FIG. 3A shows a cross-sectional view of an example multi-junction emitter 300 that enables a multi-wavelength output according to one or more implementations. FIG. 3B shows an example gain curve 305 of the multi-wavelength output corresponding the multi-junction emitter 300 of FIG. 3A according to one or more implementations. FIG. 3C shows a wavelength-intensity graph 315 corresponding to the multi-junction emitter 300 of FIG. 3A according to one or more implementations. In some implementations, the multi-junction emitter 300 may be a VCSEL device. As shown in FIG. 3A, the multi-junction emitter 300 may implement one or more components and/or aspects of the emitter 200. For example, as shown in FIG. 3A, the multi-junction emitter 300 includes the via 106, the optical aperture 108, the trenches 112, the top mirror 118, multiple active regions 122, the bottom mirror 124, the substrate layer 126, the backside cathode layer 128, and the multiple sidewall reflectors 202. In some other implementations, the multi-junction emitter 300 may include additional components and/or aspects of the emitter 200. Additionally, or alternatively, one or more components and/or aspects of the multi-junction emitter 300 shown in FIG. 3A may not be included in other implementations.

As shown in FIG. 3A, the multi-junction emitter 300 may include multiple active regions 122 (e.g., active regions 122a, 122b, and 122c). The multi-junction emitter 300 (e.g., a multi-junction VCSEL) is a type of emitter that incorporates multiple active regions 122 within a single device to enhance performance and output power. These multiple active regions 122 are formed by stacking several quantum wells or quantum dots, each separated by tunnel junctions or intermediate layers that facilitate carrier transport between the regions. In some implementations, the tunnel junctions or intermediate layers may include doped GaAs, indium gallium arsenide (InGaAs), AlGaAs, InP, and/or gallium indium phosphide (GaInP), among other examples. Each active region can be individually optimized to target specific wavelengths or to improve overall efficiency. The stacked configuration allows for increased gain and higher output power because the injected carriers can recombine in multiple active regions 122, generating more photons. The engineering of these layers, including the thickness and material composition, ensures that the active regions 122 work in concert, effectively amplifying the light as the light passes through each of the active regions 122. As shown in FIG. 3A, the multi-junction emitter 300 includes three active regions 122 (shown as active regions 122a, 122b, and 122c). In other implementations, the multi-junction emitter 300 can include any number of active regions 122.

In some implementations, the three active regions 122 (active regions 122a, 122b, and 122c) can respectively generate three wavelength outputs associated with one or more non-fundamental transverse modes (e.g., a first wavelength output (λ_{b1}), a second wavelength output (λ_{b2}), and a third wavelength output (λ_{b3})). As shown in FIG. 3B, with reference to the gain curve 305, the three wavelength outputs are respectively associated with three peak gains of three gain spectra. In some implementations, the multi-junction emitter 300 may include one or more tunnel junctions that facilitate current spreading in the horizontal direction of the multi-junction emitter 300, which enables the output of the three wavelength outputs. Additionally, the multi-junction emitter 300 may generate a fourth wavelength output (λₐ) associated with a longitudinal mode based on the top mirror 118 and the bottom mirror 124 (e.g., similar to the emitter 100 and the emitter 200).

As shown in FIG. 3C, the wavelength-intensity graph 315 includes a first intensity of the first wavelength output (λ_{b1}), a second intensity of the second wavelength output (λ_{b2}), a third intensity of the first wavelength output (λ_{b3}), and a fourth intensity of the fourth wavelength output (λₐ). In some implementations, the first, second, third, and fourth intensities may be the same or different. The first wavelength output (λ_{b1}) may be defined by a first peak gain of a first gain spectrum (e.g., 920 nm), the second wavelength output (λ_{b2}) may be defined by a second peak gain of a second gain spectrum (e.g., 923 nm), the third wavelength output (λ_{b3}) may be defined by a third peak gain of a third gain spectrum (e.g., 926 nm), and the fourth wavelength output (λₐ) may be defined by the F-P dip on a gain spectrum based on the axial resonance of the optical cavity (e.g., 940 nm).

Designing the multi-junction emitter 300 involves several considerations and/or modifications to the other emitter structures described herein (e.g., the emitter 100 or the emitter 200) to accommodate the unique requirements of multiple active regions 122 and the generation of different wavelengths (e.g., λ_{b1}, λ_{b2}, and λ_{b3}). For instance, the active media of the multi-junction emitter 300 may be optimized to support lasing at multiple wavelengths, which may involve engineering the quantum wells or quantum dots in the active regions 122 to have different bandgaps, allowing them to emit light at distinct wavelengths. The precise compositions and thicknesses of these layers enable efficient emission and amplification at the desired wavelengths (e.g., λ_{b1}, λ_{b2}, and λ_{b3}). Additionally, or alternatively, for the multi-junction emitter 300, the design of the current confinement aperture 110 (such as an oxide aperture) may be adjusted to ensure that the current confinement aperture 110 effectively confines the optical modes for all of the target wavelengths across the multiple active regions 122. Adjustments to the current confinement aperture 110 might involve optimizing the size and placement of the aperture to accommodate the different mode profiles and ensure efficient coupling of light into the vertical cavity. Additionally or alternatively, the width of the mesa and the distance between trenches 112 can be adjusted to support the different non-fundamental transverse modes (e.g., λ_{b1}, λ_{b2}, and λ_{b3}) and ensure proper mode confinement. The mesa width may be designed to support the lateral confinement of the optical modes, while the distance between trenches 112 can influence the feedback and coupling of the horizontal cavity modes. Additionally, or alternatively, the electrodes may be placed to ensure uniform current distribution across the multiple active regions 122. Such electrode placements may involve designing multi-layered electrode structures to place the electrodes in positions that minimize resistance and ensure efficient carrier injection. Additionally, or alternatively, the different non-fundamental transverse modes (e.g., λ_{b1}, λ_{b2}, and λ_{b3}) can be generated by designing the cavity and the multiple active regions 122. The transverse modes are influenced by the geometry of the cavity, the refractive index profile, the placement of the active regions 122, and/or the multiple sidewall reflectors 202. By engineering these parameters, the multi-junction emitter 300 may be configured to enhance or suppress specific transverse modes, allowing the multi-junction emitter 300 to emit at multiple non-fundamental transverse modes (e.g., λ_{b1}, λ_{b2}, and λ_{b3}).

As indicated above, FIGS. 3A, 3B, and 3C are provided as examples. Other examples may differ from what is shown in and described with regard to FIGS. 3A, 3B, and 3C.

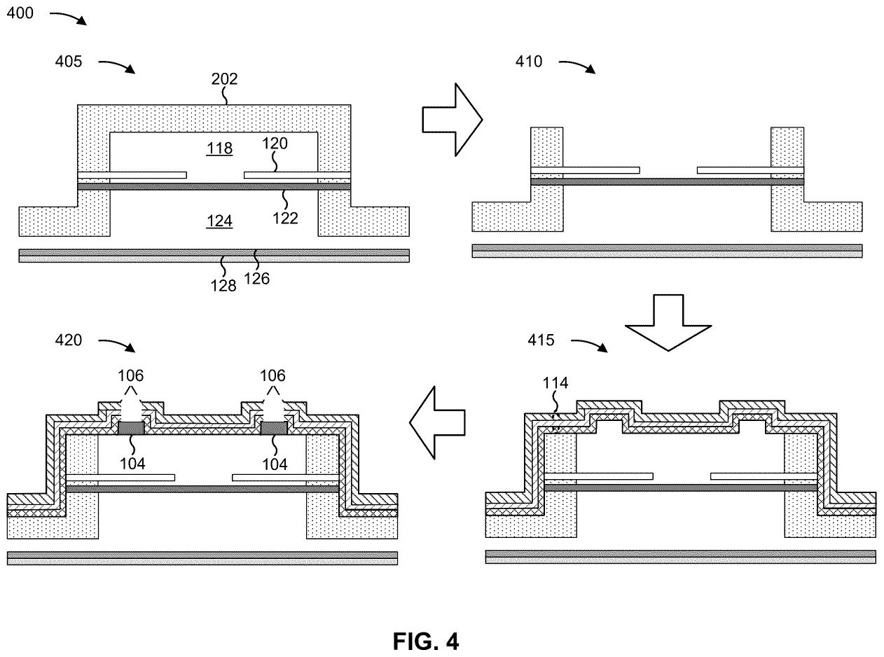

FIG. 4 shows an example fabrication process 400 for creation of multiple sidewall reflectors included in an emitter according to one or more implementations. In some examples, one or more aspects and/or operations of the fabrication process 400 may be used to construct the emitter 200 and/or the multi-junction emitter 300, described elsewhere herein. Alternative examples of the following may be implemented, where some operations are performed in a different order than described, or not described at all. In some cases, one or more operations may include additional features not mentioned below, or further operations may be added.

In a first operation 405, the multiple sidewall reflectors 202 may be deposited on top of a mesa structure of the emitter. In some examples, “mesa structure” may refer to a raised, etched region of a semiconductor material that defines the laser cavity and controls current flow of the emitter. For instance, prior to deposition of the multiple sidewall reflectors 202, the structure may include the backside cathode layer 128 and the substrate layer 126, where a set of epitaxial layers are deposited on top of the substrate layer 126 according to the techniques described elsewhere herein (e.g., the bottom mirror 124, the active region 122, the oxidation layer 120, and the top mirror 118).

In some examples, the multiple sidewall reflectors 202 may be constructed of the dielectric mirror pair 204. In such examples, the first operation 405 may include depositing alternating layers of high and low refractive index materials onto the mesa structure using techniques such as electron beam evaporation, sputtering, and/or chemical vapor deposition (CVD). The process begins with the cleaning and preparation of the mesa structure to ensure a smooth and contaminant-free surface. The deposition process involves sequentially layering materials with high and low refractive indices (such as Si₃N₄ and SiO₂). The deposition may be performed to maintain uniform thickness and composition across the entire mesa structure, ensuring uniformity across the dielectric mirror pair 204.

In some examples, the multiple sidewall reflectors 202 may be constructed of the metal layer 210. In such examples, the first operation 405 may include depositing the metal layer 210 using methods such as thermal evaporation, electron beam evaporation, and/or sputtering, among other examples. These techniques involve vaporizing the metal in a vacuum chamber and allowing the metal to condense onto the mesa surface, forming a thin, uniform layer. The deposition parameters, such as rate and thickness, are carefully controlled to achieve the desired layer characteristics. After deposition, the metal layer 210 may undergo additional processing steps, such as annealing, to improve adhesion and electrical contact.

In a second operation 410, a top surface of the material comprising multiple sidewall reflectors 202 may be etched, exposing a top portion of the mesa structure of the emitter. To expose the top portion of the mesa structure, a photolithography process may be first employed to define the etching area. A photoresist layer may be applied and patterned using a mask that corresponds to the desired exposed regions. Following the patterning, the etching process may be carried out using either wet chemical etching or dry etching techniques (such as reactive ion etching (RIE)). The etching parameters, including time, gas composition, and/or power, may be controlled to selectively remove the top surface of the material (comprising multiple sidewall reflectors 202) without damaging the underlying layers of the mesa structure. The result is an etched mesa structure with the top portion exposed such that the multiple sidewall reflectors 202 may enclose the perimeter of the lasing cavity to enable the generation of one or more non-fundamental transverse modes.

In a third operation 415, a protective layer (e.g., the protective layer 114) may be deposited. In some examples, the protective layer may include at least one layer of Si₃N₄. As described elsewhere herein, the protective layer 114 may be deposited by chemical vapor deposition, atomic layer deposition, and/or other techniques.

In a fourth operation 420, one or more vias (e.g., via 106) may be etched into the protective layer and a metal layer (e.g., the ohmic metal layer 104) may be deposited for contact. As described elsewhere herein, the via 106 may be formed as an etched portion of the protective layer 114 or a lifted-off section of protective layer 114. Additionally, the ohmic metal layer 104 may be P-ohmic, N-ohmic, or another form. Selection of a particular type of ohmic metal layer 104 may depend on the architecture of the emitter. Ohmic metal layer 104 may provide ohmic contact between a metal and a semiconductor and/or may provide a non-rectifying electrical junction and/or may provide a low-resistance contact.

As indicated above, FIG. 4 is provided as an example. Other examples may differ from what is shown in and described with regard to FIG. 4.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL) device, comprising:
a substrate layer;
a set of epitaxial layers deposited on the substrate layer;
at least one active region formed in the set of epitaxial layers; and
multiple sidewall reflectors, wherein:
the VCSEL device is configured such that electrical pumping provides an optical gain within the at least one active region for lasing at a first wavelength based at least in part on the set of epitaxial layers and lasing at a second wavelength based at least in part on the multiple sidewall reflectors.

2. The VCSEL device of claim 1, wherein the first wavelength is defined by a fundamental longitudinal mode and the second wavelength is defined by a non-fundamental transverse mode.

3. The VCSEL device of claim 1, wherein the optical gain is defined by an optical gain curve such that the first wavelength is aligned to the axial resonance of the Fabry-Pérot optical cavity and the second wavelength is aligned proximal to the gain peak of the optical gain curve.

4. The VCSEL device of claim 1, wherein the VCSEL device is configured to:
output the first wavelength according to a first wave vector that propagates in a vertical direction that is perpendicular to the set of epitaxial layers; and
output the second wavelength according to a second wave vector that propagates in a direction at a non-zero angle relative to the vertical direction based at least in part on the multiple sidewall reflectors.

5. The VCSEL device of claim 1, wherein the multiple sidewall reflectors comprise a dielectric mirror pair that includes one or more alternating layers of a first dielectric material and a second dielectric material.

6. The VCSEL device of claim 5, wherein the first dielectric material has a first refractive index that is greater than or equal to a refractive index threshold and the second dielectric material has a refractive index that is less than the refractive index threshold.

7. The VCSEL device of claim 5, wherein the first dielectric material is silicon nitride and the second dielectric material is silicon dioxide.

8. The VCSEL device of claim 1, wherein the multiple sidewall reflectors comprise one or more layers of one or more plated metals.

9. The VCSEL device of claim 8, wherein the one or more plated metals include one or more of silver, aluminum, or gold.

10. The VCSEL device of claim 1 wherein, as a temperature of the VCSEL device changes, the first wavelength changes at a first rate of change and the second wavelength changes at a second rate of change.

11. An emitter device, comprising:
a substrate layer;
a set of epitaxial layers deposited on the substrate layer;
at least one active region formed in the set of epitaxial layers; and
multiple sidewall reflectors, wherein:
the emitter device is configured such that electrical pumping provides an optical gain within the at least one active region for lasing at a first wavelength based at least in part on the set of epitaxial layers and lasing at a second wavelength based at least in part on the multiple sidewall reflectors.

12. The emitter device of claim 11, wherein the first wavelength is defined by a fundamental longitudinal mode and the second wavelength is defined by a non-fundamental transverse mode.

13. The emitter device of claim 11, wherein the optical gain is defined by an optical gain curve such that the first wavelength is aligned to the axial resonance of the Fabry-Pérot optical cavity and the second wavelength is aligned proximal to the gain peak of the optical gain curve.

14. The emitter device of claim 11, wherein the emitter device is configured to:
output the first wavelength according to a first wave vector that propagates in a vertical direction that is perpendicular to the set of epitaxial layers; and
output the second wavelength according to a second wave vector that propagates in a direction at a non-zero angle relative to the vertical direction based at least in part on the multiple sidewall reflectors.

15. The emitter device of claim 11, wherein the multiple sidewall reflectors are made out of a dielectric mirror pair that includes one or more alternating layers of a first dielectric material and a second dielectric material.

16. The emitter device of claim 15, wherein the first dielectric material has a first refractive index that is greater than or equal to a refractive index threshold and the second dielectric material has a refractive index that is less than the refractive index threshold.

17. The emitter device of claim 15, wherein the first dielectric material is silicon nitride and the second dielectric material is silicon dioxide.

18. The emitter device of claim 11, wherein the multiple sidewall reflectors are made out of one or more layers of one or more plated metals.

19. The emitter device of claim 11 wherein, as a temperature of the emitter device changes, the first wavelength changes at a first rate of change and the second wavelength changes at a second rate of change.

20. A vertical cavity surface emitting laser (VCSEL) device, comprising:
a substrate layer;
a set of epitaxial layers deposited on the substrate layer;
a plurality of active regions formed in the set of epitaxial layers; and
multiple sidewall reflectors, wherein:
the VCSEL device is configured such that electrical pumping provides an optical gain within the plurality of active regions for lasing at a first wavelength based at least in part on the set of epitaxial layers and lasing at a plurality of second wavelengths are based at least in part on the multiple sidewall reflectors, and
the plurality of second wavelengths are respectively associated with the plurality of active regions.
